(19) United States
(12) Patent Application Publication
(10) Pub. No.: US 2022/0001907 A1
(43) Pub. Date: Jan. 6, 2022

(54) Electronic Device Enclosure and Mount for Shopping Carts

(71) Applicant: Scott Wells, Dagsboro, DE (US)

(72) Inventor: Scott Wells, Dagsboro, DE (US)

(21) Appl. No.: 17/366,798

(22) Filed: Jul. 2, 2021

Related U.S. Application Data
(60) Provisional application No. 63/047,947, filed on Jul. 3, 2020.

(51) Int. Cl. B62B 3/14; H05K 5/02

(52) U.S. Cl. CPC B62B 3/1428; H05K 5/0221; H05K 5/0204

(57) ABSTRACT

An electronic device enclosure for retail shopping carts is disclosed having a cart mounting bracket attached to the side of a shopping cart near the front handle cross bar that does not interfere with the nesting of the cart as it was designed. An enclosure comprising a housing for an electronic device such as a tablet computer has a mounting bracket being incorporated into the rear of the housing and further having a mounting arm containing secured locking means to securely seat into the cart mounting bracket. The apparatus further contains means of transmitting via NFC to a CPU or to one of several networked CPU beacons docking confirmation and location data. The cart mount bracket is designed to withstand prolonged outdoor weather conditions without malfunctioning.

### FIELD OF INVENTION

The present invention relates to the field of electronic device enclosures, specifically mountable electronic device enclosure solutions for retail shopping carts.

### BACKGROUND OF THE INVENTION

The consumer retail brick-and-mortar sector, including grocery, membership clubs and department stores, are allocating significant resources into apps and new technology to improve the in-store customer experience. Online shopping, omnichannel strategies, artificial intelligence, and a global health pandemic have fundamentally and permanently changed the old retail business model. Each retailer has invested significant time and money into their dedicated mobile/web app to address the needs of the modern tech savvy consumer. The in-store experience is being enhanced by mobile apps, but due to phone screen size limitations, multi-tasking and multi-app usage by customers while shopping in-store, and the unavailability of in-store proximity marketing due to personal device privacy, the full potential of the digital experience is limited. Providing a kiosk at the front of the shopping cart that accesses only the retailer's app and the shopper's personal retail account delivers a new level of engagement and hands-free shopping for the next generation of in-store retail shopping.

Several attempts have been made to integrate kiosks and electronic devices into shopping carts, such as in the Docking Apparatus to Grizwok, et. al, U.S. Pat. No. 9,650,810; Mobile Device Holder to Merskey, U.S. Pat. No. 8,474,832; Shopping Apparatus and Methods to Crum, U.S. Pat. No. 8,336,744; and Apparatus, System, and Method for Self-Service Shopping to Hutchings, et. al., U.S. Pat. No. 10,573,153. Several flaws exist in prior art that are addressed by the present application. None of the prior art solutions are practical for or make claims to weather durability and capability of the invention to withstand outdoor an indoor usage. Almost all the prior art does not allow for nesting of shopping carts when not in use due the positioning of the mount and enclosure. Means of disconnecting the tablet enclosure from the mounting arm for storage, charging, or repair by a locking mechanism such as a barrel lock, electromechanical lock, or other means are also not found in the prior art. Other design flaws in the prior art are also unaddressed while others are improved upon by the present invention.

The present invention solves the shortcomings of the prior art by providing a novel electronic device enclosure, connection means and a mount for a shopping cart. The electronic device may be a tablet, smart phone, kiosk, or other similar mobile computer device. This addresses a long felt need in the industry by presenting a novel and unique solution for retailers to better utilize their existing software applications to engage customers in-store and provide a unique shopping experience.

A first object of the invention is to provide an enclosure for an electronic device such as (but not limited to) a tablet or other electronic kiosk or device of similar dimension to a tablet computer.

A second object of the invention is to provide a mount for said enclosure capable of being affixed to any style of rolling shopping cart used by retailers such as supermarkets, department stores and warehouse stores and that can be either be designed to be removable or can be permanently attached to the shopping cart by a locking means including but not limited to: a barrel lock, keyed cylinder lock, warded mechanism, lever tumbler mechanism, disk tumbler (or wafer) mechanism, or pin tumbler mechanism; or an electromechanical locking means including but not limited to a electromagnetic lock or magnetically keyed or magnetic-coded lock. Locking means may be located either by the point of connection with the shopping cart on the cart mount bracket portion of the apparatus or between the mounting bracket arm and the device enclosure.

A third object of the invention is to provide a unique and novel locking means whereby the mount may be securely locked onto to mount and is capable of being removed for charging, storage, and repair when not in use by a consumer.

A fourth object of the invention is to provide an enclosure, mount, and connection means for an electronic device to attach or affix to a shopping cart that can withstand harsh outdoor weather conditions such as extreme heat or wet weather.

A fifth object of the invention is to provide an enclosure and mount for an electronic device to connect to a shopping cart that does not interfere with the shopping carts' ability to nest.

The above and other objects, features and advantages of the present invention should become more readily apparent to those skilled in the art upon a reading of the following detailed description in conjunction with the drawings, wherein there is shown and described illustrative embodiments of the invention.

### BRIEF DESCRIPTION OF THE DRAWINGS

In the following detailed description, reference will be made to the attached drawings in which:

FIG. 1 shows an embodiment of the invention wherein a mount is permanently affixed to a shopping cart, and a device enclosure is permanently affixed to a connection interface having an arm that can be docked with, and locked or unlocked to, the mount. The invention is shown in its locked state ready to be used in-store by a customer.

FIG. 2 shows the embodiment of the invention of FIG. 1 in its unlocked state where the mounting arm is removed from the mounting bracket that is permanently affixed to the shopping cart.

FIG. 3 shows an additional embodiment of the invention wherein the entire mount and enclosure are permanently affixed to each other and are removable as one unit and can be locked or unlocked to a shopping cart. The invention is shown in its locked state ready to be used in-store by a customer.

FIG. 4 shows the embodiment of the invention of FIG. 3 in its unlocked state whereby the entire mount and enclosure are removed as one unit from the shopping cart.

FIG. 5 shows another embodiment of the present invention wherein the mount and connection arm are permanently affixed to the shopping cart; and wherein the device enclosure docks to the connection arm of the mount and can be locked and unlocked from the connection interface point of the connection arm. The invention is shown in its locked state ready to be used in-store by a customer.

FIG. 6 shows the embodiment of the invention of FIG. 5 in its unlocked state wherein the so enclosure is removed from the connection arm and mount.

FIG. 7 shows a side-by-side comparison of three embodiments of the invention featured in FIGS. 1-6.

It is to be understood that while a preferred embodiment of the invention is illustrated, it is not to be limited to the specific form or arrangement of parts herein described and shown. It will be apparent to those skilled in the art that various changes may be made without departing from the scope of the invention and the invention is not to be considered limited to what is shown and described in the specification and drawings.

### DESCRIPTION OF THE PREFERRED EMBODIMENTS OF THE INVENTION

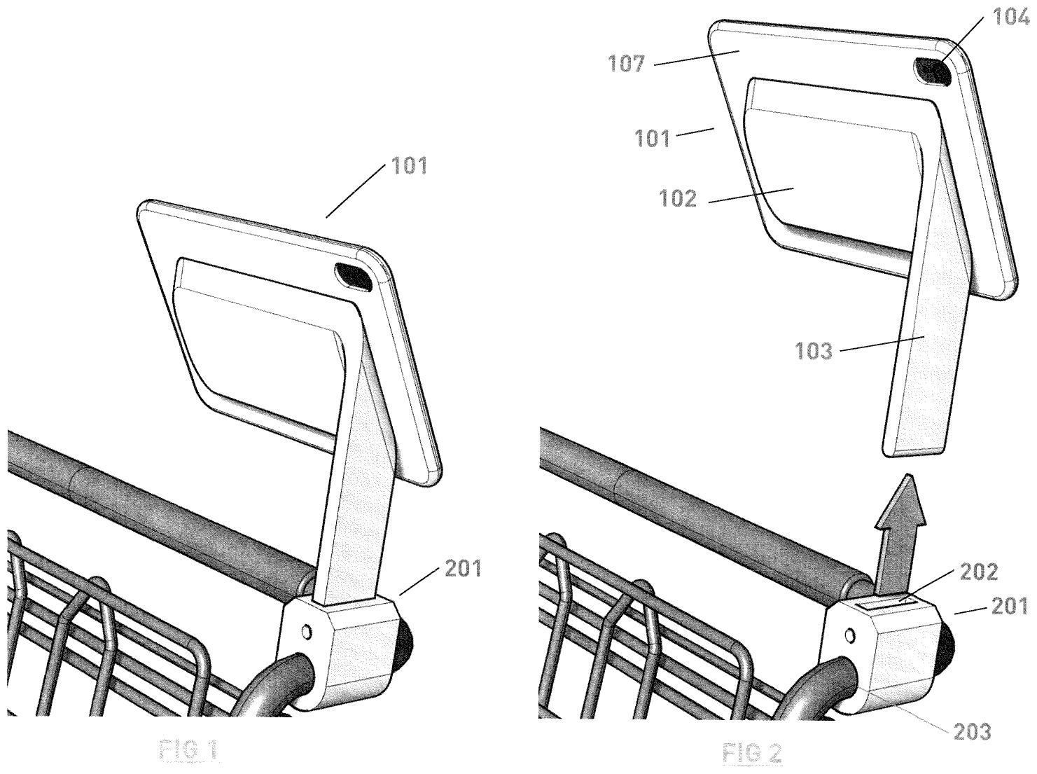

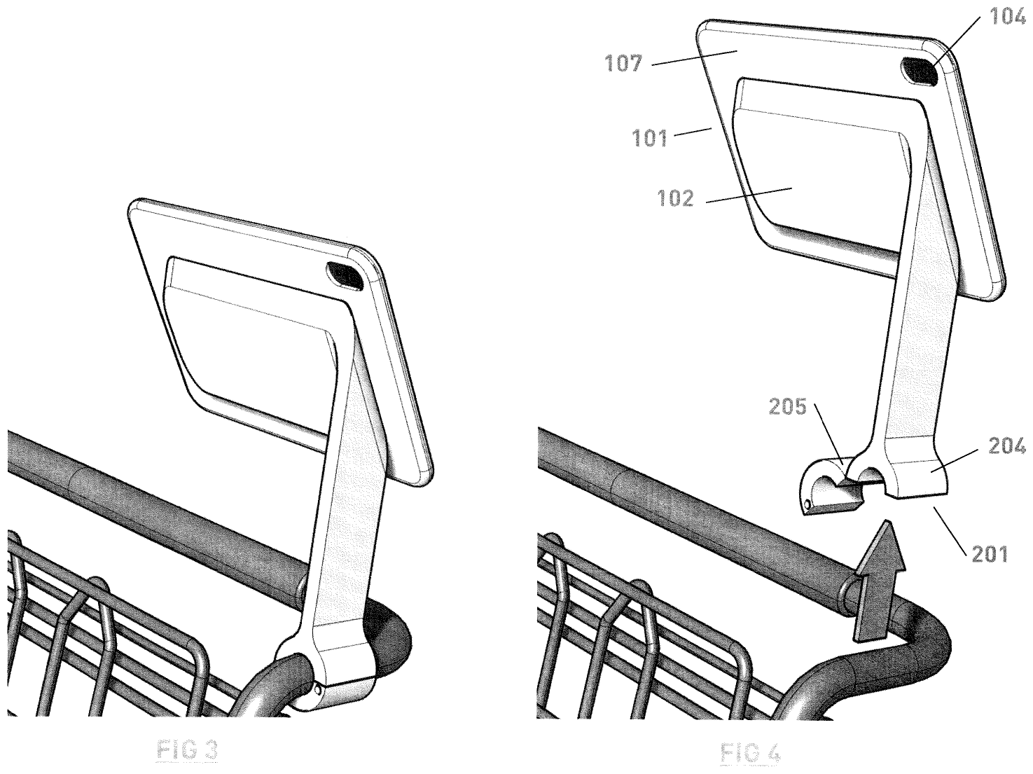

The embodiment of the invention shown in FIGS. 1 and 2 show an electronic device enclosure (101) designed to permanently attached to the tablet case (107). The tablet case (107) can be designed to fit any size tablet or similar kiosk and have cut-outs to accommodate forward or back-facing cameras, screens, and charging ports per the specific tablet configuration (104). The tablet case (107) may also be designed to lock and unlock an encased electronic device to allow for maintenance or replacement as needed. The backside of electronic device enclosure (101) seen in FIGS. 1 and 2 has a mounting bracket (102) that may either be rigid or designed with a swivel capability to allow the housing (107) to rotate to switch between portrait and landscape orientations.

The mounting bracket (102) also encompasses a mount connection arm (103) with connection means to attach to a cart mount bracket (201) on the shopping cart. “Connection means” may include a barrel lock, keyed cylinder lock, warded mechanism, lever tumbler mechanism, disk tumbler (or wafer) mechanism, or pin tumbler mechanism; or an electromechanical locking means including but not limited to a electromagnetic lock or magnetically keyed or magnetic-coded lock. The mount arm (103) is designed to be a certain minimum width to provide strength and stability to the device enclosure (101), supporting the of the enclosure and the anticipated wear and tear accompanying frequent use. The mount arm (103) may also be designed to allow the tablet to rest at an optimal viewing angle can may also be designed with forward and back rotation capability to adjust the viewing angle of the display. A cart mounting bracket (102) is permanently affixed to a cart (203) and can be designed to attach anywhere near the handle end of the shopping cart including the side of the cart. In the preferred embodiment of the invention the cart mounting bracket is attached to a side of the shopping cart near the front handle as shown in the drawings, or in any position where it would not interfere with the nesting of the shopping cart as that cart was originally designed to do. The mount will also have a connection interface (202) to receive the mount arm (103) where the entire electronic device enclosure (101) locks into place with a barrel lock or other locking connection means (not shown).

The cart mount (201) can also be designed to include electromechanical or NFC means such as Bluetooth® to send a signal to a CPU or to one of a series of connection CPU beacons capable of electronically receiving and transmitting digital data confirming that the device is locked in place on a shopping cart and ready for use, or may relay location information, or other data about the electronic device. In this embodiment of the invention, the entire tablet enclosure and connection means are permanently connected as if they were one piece and are docked with the mounting bracket (102) which is design to be permanently affixed to the shopping cart.

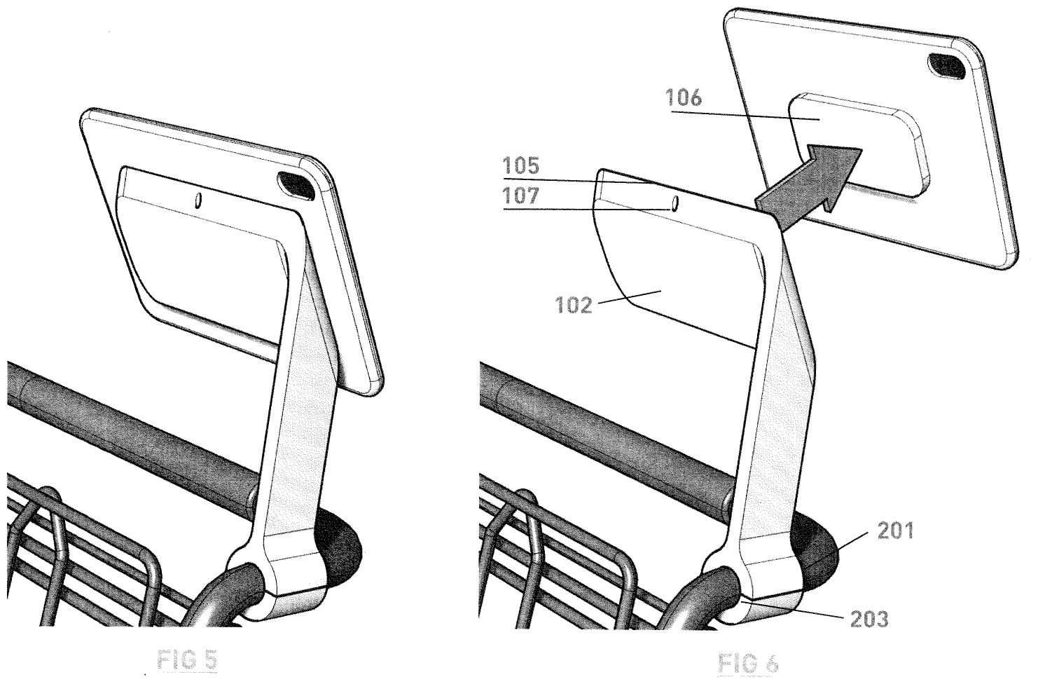

FIGS. 3 and 4 show an alternative embodiment of the invention wherein the electronic device enclosure's (101) connection means, a mounting arm (103) and mounting bracket (102) and the cart mount (201), are all features of one contiguous structure and is affixed to a shopping cart, and can be locked or unlocked to be taken on or off as required via a barrel lock or other locking means (not shown). This embodiment also shows the cart mount (201) being generally round-shaped (204) as opposed to the generally block shaped design shown in FIGS. 1 and 2 and having a swivel (205) that allows the mount to open and close and latch around the arm of a shopping cart. The ability for the tablet enclosure (101) to be removable from the shopping cart to allow for convenient service, repair, and possibly for charging of the electronic device.

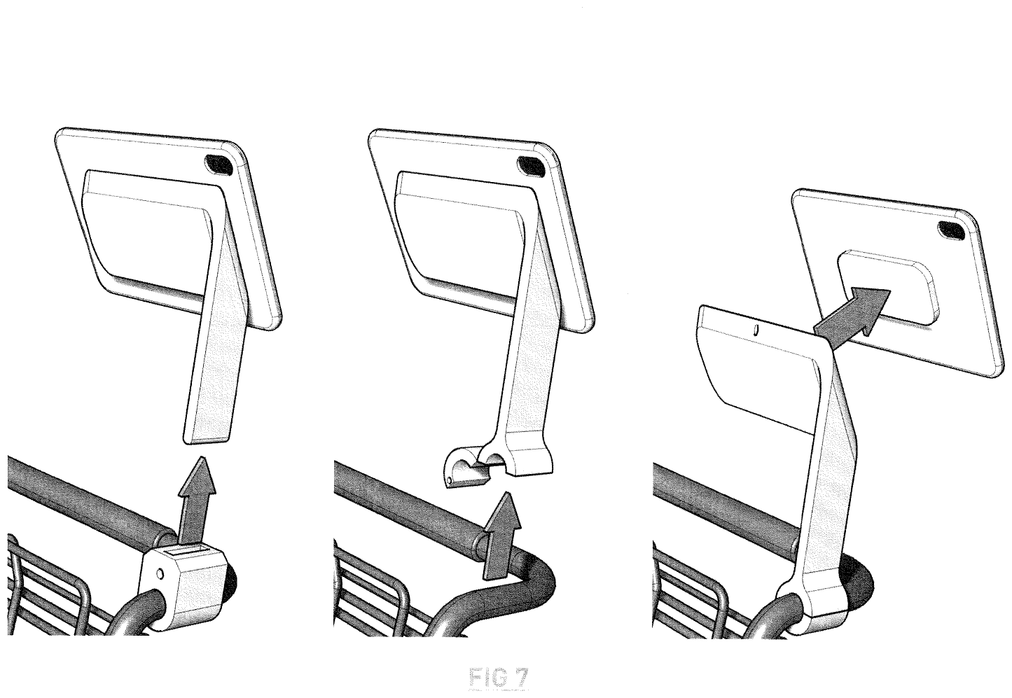

FIGS. 5 and 6 of the present invention shows another embodiment of the invention wherein the electronic device enclosure (101) has a housing (107) is affixed to the connection means (102) via a bracket on the rear of the housing (106) and can be locked or unlocked at the point of contact between the tablet enclosure (101) and connection means (105) via a barrel lock or other locking means. The connection means (102) having an arm (103) is all one contiguous piece and is permanently attached to the shopping cart (203).

In any of the embodiments of the invention, the cart mount (201) can be designed to be any shape that best accommodates the originally designed nesting functionality of the shopping cart, such as a block-shape as in FIGS. 1 and 2, or have a more contoured, rounded-shape as shown in FIGS. 3-6. In the embodiment of FIGS. 5 and 6, the entire cart mount (201) and connection means (103) are all one piece and stay on the shopping cart while the electronic device enclosure (101) is removable to allow for repair, replacement, or charging separate from the shopping cart or cart mount.

In all the embodiments herein described, the elements of the invention are comprised of a metal alloy, plastic polymer or other material designed to withstand extreme weather situations including but not limited to extreme heat and wet weather, resistance to bending, scratching or other stress, and have the durability to withstand frequent use indoors and outdoors. Unlike the prior art, present invention and the embodiments described herein are designed not only to be used in-store by consumers, but to travel with the consumers outside to the store and sit in a parking lot, and also allow the shopping carts to nest in the most practical means possible as the cart was originally intended and designed to do. These features of the present invention are a unique and nonobvious improvement over the prior art.

It is to be understood that while a preferred embodiment of the invention is illustrated, it is not to be limited to the specific form or arrangement of parts herein described and shown. For example, the invention can be designed to mount onto any feature near the handle end of the cart. The preferred embodiments herein shown and described have the mounting bracket located on the sidebar of the handle; but the mount may for example be positioned on the crossbar behind the handle, depending on the design of a specific cart. The mounting bracket can be any shape beyond the generally block-shaped or rounded-shape designs shown in FIGS. 1 and 2 respectively. The mounting arm, connection means, and other design elements of the present invention may likewise have a different shape than what is shown in the Figures.

Other embodiments of the present invention not fully described herein may provide for access to the electronic device within the case or charging of the electronic device while still mounted on the cart. The use of terms “such as” and “including” in this specification are used to provide examples and should not be interpreted as limiting the scope of the invention. It will be apparent to those skilled in the art that various changes may be made without departing from the scope of the invention and the invention is not to be considered limited to what is shown and described in the specification and drawings.

What is claimed is:

1. An electronic device enclosure and connection apparatus for a shopping cart, comprising:
a housing for an electronic device;
a mounting bracket being incorporated into the rear of said housing having a mechanism allowing for forward, backward and rotational movement of said housing to adjust the viewing angle of the electronic device enclosure;
a mounting arm extending downward from said mounting bracket containing secured locking means of attachment to a shopping cart comprising a barrel lock, keyed cylinder lock, warded lock, an electromechanical lock, magnetically-keyed or magnetic coded locking mechanism;
said mounting arm further housing means of electronically transmitting docking and location data via NFC to a CPU terminal or to one of a series of networked CPU beacons;
a cart mount bracket housing a connection interface point capable of seating and securing said mounting arm by said locking means;
said connection interface point being an electromechanical or magnetically-keyed or magnetic coded locking mechanism;
said cart mount bracket being affixed to an area along a side of the shopping cart near the shopping cart's front handle crossbar in a manner that would not interfere with the shopping cart's nesting capability.

2. The electronic device of claim 1 being a tablet computer or smart phone.

3. The apparatus of claim 1, wherein said cart mount bracket is capable of withstanding prolonged use and exposure to outdoor weather including extreme heat and cold and raining conditions, without malfunctioning.

4. An electronic device enclosure and connection apparatus for a shopping cart, comprising:
a housing for an electronic device;
a mounting bracket being incorporated into the rear of said housing having a mechanism allowing for forward, backward and rotational movement of said housing to adjust the viewing angle of the electronic device enclosure;
a cart mount bracket being affixed to an area along a side of the shopping cart near the shopping cart's front handle crossbar in a manner that would not interfere with the shopping cart's nesting capability;
said cart mount bracket further comprising a mounting arm and having means of electronically transmitting docking and location data via NFC to a CPU terminal or to one of a series of networked CPU beacons, and further having a connection interface point;
said connection interface point having secured locking means of attachment to said mounting bracket that may be a barrel lock, keyed cylinder lock, warded lock, or an electromechanical or magnetically keyed or magnetic coded locking mechanism;
said connection interface point being an electromechanical or magnetically keyed or magnetic coded locking mechanism securely receiving and docking the mounting arm to said housing.

5. The electronic device of claim 1 being a tablet computer or smart phone.

6. The apparatus of claim 1, wherein said cart mount bracket is capable of withstanding prolonged use and exposure to outdoor weather including extreme heat and cold and raining conditions, without malfunctioning.
